(19) United States
(12) Patent Application Publication
(10) Pub. No.: US 2006/0222032 A1
(43) Pub. Date: Oct. 5, 2006

(54) Optical semiconductor element, method of manufacturing optical semiconductor element and optical module

(76) Inventors: Yasushi Sakuma, Tokyo (JP); Katsuya Motoda, Yokohama (JP); Kaoru Okamoto, Yokohama (JP); Ryu Washino, Chigasaki (JP)

Correspondence Address: MCDERMOTT WILL & EMERY LLP, 600 13TH STREET, N.W., WASHINGTON, DC, 20005-3096, US

(21) Appl. No.: 11/215,122

(22) Filed: Aug. 31, 2005

(30) Foreign Application Priority Data
Mar. 16, 2005 (JP) 2005-074991

(51) Int. Cl. H01S 5/00

(52) U.S. Cl. 372/50.1

(57) ABSTRACT

An InGaAsP thin film layer having the same index of refraction as a diffraction grating is inserted between a p-type InP clad layer and the diffraction grating composed of an InGaAsP layer. In this structure, the InGaAsP layer is present over an active layer, and the amount of thermal diffusion of dopant to the vicinity of the active layer does not depend on an aperture width or the presence or absence of the diffraction grating when the p-type InP clad layer is grown, thereby obtaining a stable optical output, a threshold current, and slope efficiency.

### CLAIM OF PRIORITY

The present application claims priority from Japanese patent application serial no. 2005-074991, filed on Mar. 16, 2005, the content of which is hereby incorporated by reference into this application.

### BACKGROUND OF THE INVENTION

1. Field of the Invention

The present invention relates to an optical semiconductor element, a method of manufacturing the optical semiconductor element, and an optical module which are able to use in the field of optical communications and so on.

2. Description of the Related Art

As optical communications systems have increased in speed and functionality in recent years, semiconductor lasers with high wavelength stability have been demanded as the light sources of the systems. Semiconductor lasers for communications are distributed feedback (DFB) lasers having an excellent single wavelength property.

DFB lasers have an excellent single wavelength property because an oscillation wavelength is defined by a diffraction grating provided in a laser structure. In a buried heterostructure DFB laser, a multilayer structure for laser oscillation is formed by crystal growth, and then a diffraction grating pattern which is periodically stepped is formed on an upper guide layer by an interference exposure apparatus and wet etching. A p-type InP clad layer and a contact layer undergo crystal growth so as to fill in periodic steps, and then a mesa stripe serving as an optical waveguide is formed by etching. The side of a semiconductor mesa and an end region are filled with an semi-insulating compound semiconductor. In this structure, a diffraction grating layer having a thickness of several tens nm is formed on a surface of the upper guide layer by wet etching. Wet etching, however, has poor controllability in the depth direction, thereby degrading laser characteristics including an optical output, a threshold current, and a slope efficiency (inclination of optical output power vs current curve) which are variables of the thickness of the diffraction grating.

As a structure for improving the depth control of a diffraction grating layer, a floating diffraction grating is available in which an InP layer serves as an etching stop layer under the diffraction grating layer. JP-A No. 2004-179274 describes that the structure of a floating diffraction grating can provide stable element characteristics with no variations in the depth direction.

However, when a p-type InP clad layer is grown, an InGaAsP layer serving as a diffraction grating and an InP layer serving as an etching stop layer are different from each other in the solid solubility of p-type dopant. Thus, in the structure described in JP-A No. 2004-179274, the amount of thermal diffusion of the dopant to the vicinity of an active layer tends to depend on an aperture width or the presence or absence of a diffraction grating. The amount of thermal diffusion affects element characteristics such as an optical output power, a threshold current, and slope efficiency. Consequently, an optical semiconductor element described in JP 2004-179274 A includes factors that may reduce the manufacturing yield of the optical semiconductor element.

### SUMMARY OF THE INVENTION

An optical semiconductor element has an InGaAsP thin film layer inserted between a p-type InP clad layer and a diffraction grating composed of an InGaAsP layer. In this structure, a diffusion prevention layer having a high solid solubility of p-type dopant is present over an active layer. Thus, the amount of thermal diffusion of the dopant to the vicinity of the active layer does not depend on an aperture width or the presence or absence of a diffraction grating when the p-type InP clad layer is grown, thereby obtaining a stable optical output power, a threshold current, and slope efficiency.

### BRIEF DESCRIPTION OF THE DRAWINGS

Preferred embodiments of the present invention will now be described in conjunction with the accompanying drawings, in which:

FIG. 1 is a perspective view showing a buried heterostructure semiconductor laser including a floating diffraction grating;

FIG. 2 is a sectional view taken along a waveguide of FIG. 1;

FIG. 3 is a perspective view showing a ridge waveguide semiconductor laser including a floating diffraction grating;

FIG. 4 is a sectional view taken along a groove beside a waveguide of FIG. 3; and

FIG. 5 is a block diagram for explaining the configuration of an optical module.

### DETAILED DESCRIPTION OF THE PREFERRED EMBODIMENTS

Referring to the accompanying drawings, embodiments of the present invention will be described below in accordance with the following examples. The same members are indicated by the same reference numerals and a repeated explanation thereof is omitted.

### EXAMPLE 1

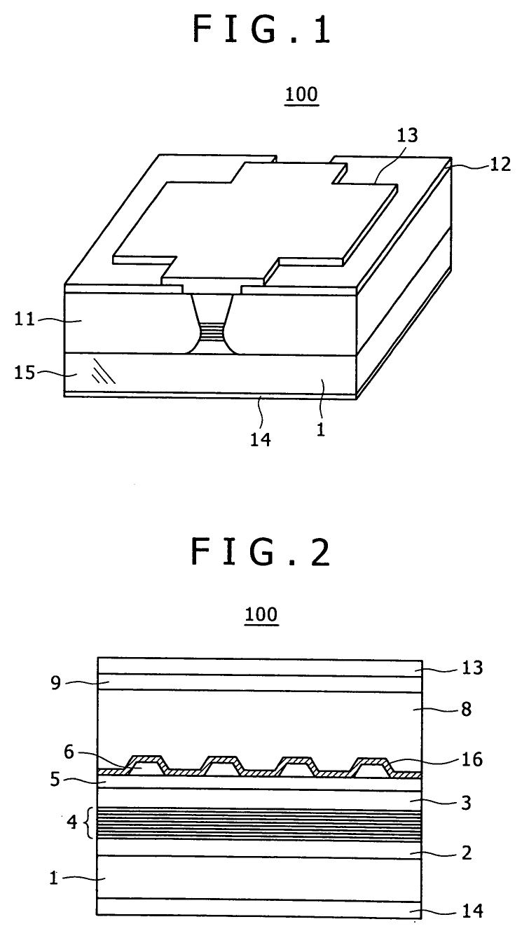

Referring to FIGS. 1 and 2, Example 1 of an optical semiconductor element will be discussed below. FIG. 1 is a perspective view showing a buried heterostructure semiconductor laser including a floating diffraction grating. FIG. 2 is a sectional view taken along a waveguide of FIG. 1.

Referring to FIGS. 1 and 2, the following will describe the manufacturing process of an optical semiconductor element 100. First, a multilayer structure is formed on an InP substrate 1 by metal-organic chemical vapor deposition (MOCVD). In the multilayer structure, a lower guide layer 2, an InGaAsP multiple quantum well active layer 4, an InGaAsP upper guide layer 3, an InP etching stop layer 5, an InGaAsP layer 6 serving as a diffraction grating, and an InP cap layer (not shown) serving as the protection layer of the InGaAsP layer 6 are formed in this order. After the InP cap layer is removed, a photo resist is coated and a photo resist pattern with a period of about 200 nm is formed on the diffraction grating layer 6 by an interference exposure apparatus. The InGaAsP layer 6 is selectively etched by wet etching to form periodic steps (diffraction grating) with the photo resist pattern serving as a mask. At this point, etching is stopped on the InP etching stop layer 5 disposed under the diffraction grating layer 6. Thus, it is possible to easily control a diffraction grating Duty (diffraction grating interval/diffraction grating period) which is a factor determining the oscillation wavelength of the laser and a grating depth which is a factor determining laser output power.

Thereafter, a p-type InP clad layer 8, a contact layer 9, and an InGaAsP thin film layer 16 almost identical in composition to the InGaAsP layer 6 are epitaxially grown by MOCVD so as to fill in the periodic steps.

In the process of epitaxial growth, the substrate is entirely heated to about 600 ° C., and thus thermal diffusion of dopant occurs from the p-type InP clad layer 8. However, since the InGaAsP layer 3 having a high solid solubility of dopant is present over the active layer, the amount of thermal diffusion of dopant does not depend on an aperture width or the presence or absence of a diffraction grating. Consequently, it is possible to obtain a stable optical output power, a threshold current, and slop efficiency.

Subsequently, to form a semiconductor mesa acting as an optical waveguide, a mesa stripe structure is formed by wet etching using Br-methanol etchant. An SiO₂ film (not shown) having been formed by CVD with a thickness of 300 nm is used as a mask. The mesa strip structure has a reversed-mesa shape with an active layer having a width of 2 μm. Thereafter, SiO₂ is removed and an SiO₂ film (not shown) is conversely formed on the semiconductor mesa. According to this selective growth using the SiO₂ mask, both sides of the semiconductor mesa are subjected to buried growth by a semi-insulating film (Fe-InP) 11 using Fe as dopant.

After the stripe SiO₂ film is removed, a passivation film 12 having a thickness of 500 nm is formed over the substrate by CVD. Only the passivation film serving as a current injection region on the semiconductor mesa is opened by photolithography and etching, and a p-side electrode 13 made of Ti/Pt/Au with a thickness of about 1 μm is formed by electron beam (EB) vapor deposition. Then, after the p-side electrode 13 is patterned by ion milling, the back side of the substrate is ground to a thickness of 100 μm, an n-side electrode 14 is formed, and the process of an electrode alloy is performed, in which a semiconductor and a metal are mutually diffused.

After these processes, a wafer is cleaved into a bar having an element length of 200 μm, a reflection protecting film 15 (\\\ in FIG. 1) is formed on a cleavage plane, and then the element is cut into chips.

With the optical semiconductor element of the present example, the threshold current was reduced from 10 mA to 5.0 mA at 25° C. The slope efficiency was increased from 0.2 W/A to 0.33 W/A. Further, the maximum optical output power was increased by 66%.

The optical semiconductor element of the present example dramatically improved the manufacturing yield of the semiconductor laser. The manufacturing yield is affected by thermal diffusion of dopant in a crystal growth process.

In this case, the material of the active layer is InGaAsP. The material may be InGaAlAs and is not particularly limited. In the present example, the InGaAsP diffraction grating and thin film layer are used. As a matter of course, an InₓGa₍₁₋ₓ₎As_{y}P_{(1-y)} (0≦x≦1, 0≦y 1) crystal may be used. The present example described a buried heterostructure and is also applicable to a ridge waveguide structure.

The above example described a semiconductor laser. An electro absorption/distributed feedback (EA/DFB) laser is also applicable. The lasers both have optical semiconductor elements.

The InGaAsP thin film layer 16 is acceptable when the thin film layer 16 has almost the same index of refraction as the InGaAsP layer 6. The InGaAsP thin film layer 16 is a diffusion prevention layer for preventing the dopant of the p-type InP clad layer from thermally diffusing to the active layer. The above modification is applicable to the other examples of this specification.

### EXAMPLE 2

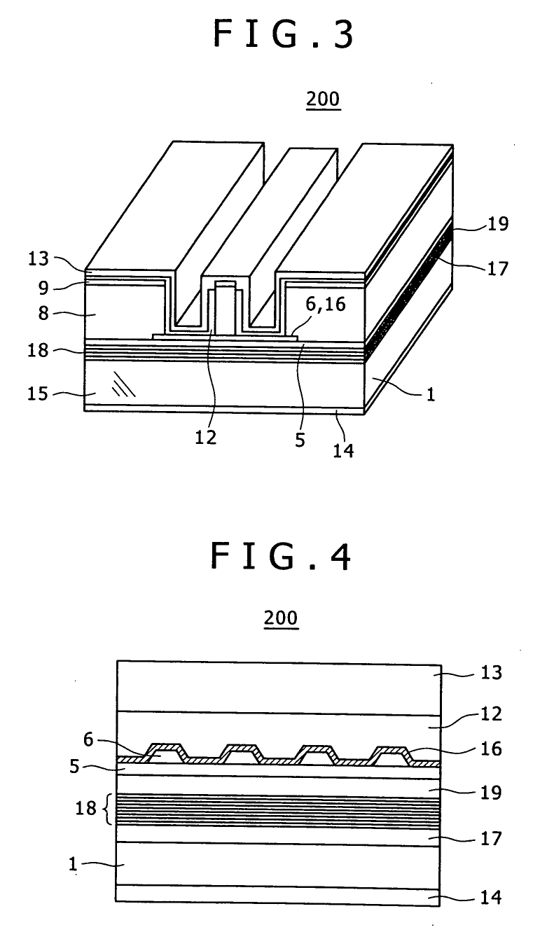

Referring to FIGS. 3 and 4, Example 2 of an optical semiconductor element will be discussed below. FIG. 3 is a perspective view showing a ridge waveguide semiconductor laser including a floating diffraction grating. FIG. 4 is a sectional view taken along a groove beside a waveguide of FIG. 3.

Referring to FIGS. 3 and 4, the following will describe the manufacturing process of an optical semiconductor element 200. First, to form an optical waveguide, a multilayer structure is formed on an InP substrate 1 by metal-organic chemical vapor deposition (MOCVD). In the multilayer structure, an n-type InAlAs layer 17, an InGaAlAs multiple quantum well active layer 18, a p-type InAlAs layer 19, an InP etching stop layer 5, an InGaAsP layer 6 serving as a diffraction grating layer, and an InP cap layer (not shown) serving as the protection layer of the InGaAsP layer 6 are formed in this order. Then, the InP cap layer is removed. After a photo resist is coated, a photo resist pattern with a period of about 200 nm is formed by an interference exposure apparatus on a part where the waveguide of the InGaAsP layer 6 is formed. The InGaAsP layer 6 is selectively etched by wet etching to form periodic steps with the photo resist pattern serving as a mask.

Thereafter, a p-type InP clad layer 8, a contact layer 9, and an InGaAsP thin film layer 16 having almost the same index of refraction as the refraction grating layer are epitaxially grown by MOCVD so as to fill in the periodic steps.

In the process of epitaxial growth, the substrate is entirely heated to about 600° C., and thus thermal diffusion of dopant occurs from the p-type InP clad layer 8. However, since the InAlAs layer 19 having a high solid solubility of dopant is present over the active layer, the amount of thermal diffusion of dopant does not depend on an aperture width or the presence or absence of a diffraction grating. Consequently, it is possible to obtain a stable optical output power, a threshold current, and slop efficiency.

The contact layer 9 is worked into a stripe structure with a stripe width of 2.0 μm and a groove width of 10 μm on both sides of the stripe. An SiO₂ film (not shown) having been formed by CVD with a thickness of 300 nm is used as a mask.

Then, after the SiO₂ film is entirely removed, the p-type InP clad layer 8 is selectively etched by wet etching using a mixed solution of hydrochloric acid and phosphoric acid while the contact layer 9 having been worked into the stripe structure is used as a mask, so that a reversed-mesa ridge waveguide is formed.

In the case where the InGaAsP thin film layer 16 is absent, etching is performed on not only the p-type InP clad layer 8 but also on the InP etching stop layer 5 during the formation of the reversed-mesa ridge waveguide, and the etching stops on the p-type InAlAs layer 18. Thus, in the working process, a material containing Al is exposed on a crystal surface. Al is oxidized, a leakage current component is generated through a surface of the oxidized Al, and thus a threshold current increases. In contrast, in the present example, the etching of the p-type InP clad layer 8 stops on the InGaAsP thin film layer 16 and thus the p-type InAlAs layer 19 disposed below the InGaAsP thin film layer 16 is not exposed or oxidized during the manufacturing process. Therefore, it is possible to reduce a threshold current and increase a slope efficiency.

Subsequently, an SiO₂ passivation film 12 having a thickness of 500 nm is formed over the substrate by CVD. Only the passivation film serving as a current injection region on the semiconductor mesa is opened by photolithography and etching, and a p-side electrode 13 made of Ti/Pt/Au with a thickness of about 1 μm is formed by EB vapor deposition. After the p-side electrode 13 is patterned (not shown) by ion milling, the back side of the substrate is ground to a thickness of 100 μm, an n-side electrode 14 is formed, and the process of an electrode alloy or the like is performed.

After these processes, a wafer is cleaved into a bar having an element length of 200 μm, a reflection protecting film 15 is formed on a cleavage plane, and then the element is cut into chips.

The semiconductor laser of the present example has an Al ridge structure with excellent laser characteristics at high temperatures, and thus the threshold current was reduced from 22 mA to 16 mA at a high temperature of 85° C. The slope efficiency was increased from 0.15 W/A to 0.2 W/A. Further, the maximum optical output power was increased by 66%.

According to the present example, the threshold current was reduced and the slope efficiency was increased in the semiconductor laser, thereby manufacturing a high-quality optical semiconductor element with a high yield.

The active layer may be made of either InGaAsP or other materials. The InGaAsP thin film layer 16 also acts as a diffusion prevention layer and an etching stop layer.

### EXAMPLE 3

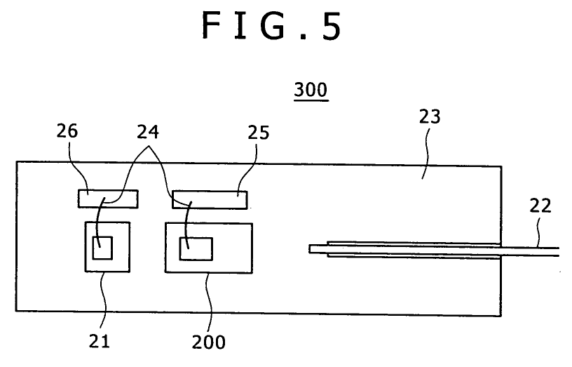

Referring to FIG. 5, Example 3 of an optical module will be discussed below. FIG. 5 is a block diagram for explaining the configuration of the optical module.

In FIG. 5, an optical module 300 has an optical fiber 22 mounted in the groove of a silicon substrate 23 and a semiconductor laser 200 mounted on the silicon substrate 23. The semiconductor laser 200 is aligned with the optical fiber 22. A waveguide light-receiving element 21 is mounted on the silicon substrate 23 so as to monitor light in the rear of the semiconductor laser. The semiconductor laser 200 and the waveguide light-receiving element 21 are respectively connected to terminals 25 and 26, which are mounted on the silicon substrate 23, via bonding wires 24. The terminals 25 and 26 are connected to external terminals (not shown).

The optical module 300 includes a housing (not shown). The input terminal of the optical fiber and optical components mounted on the silicon substrate 23 are housed in the housing.

The optical module of the present example has an Al ridge structure with excellent laser characteristics at high temperatures, and thus a threshold current was reduced from 22 mA to 16 mA at a high temperature of 85° C. A slope efficiency has been increased from 0.15 W/A to 0.2 W/A. Further, the maximum optical output was increased by 66%.

The optical module of the present example has been manufactured at low cost because of the high yield of the semiconductor laser.

The semiconductor laser of the present example may be the semiconductor laser 100 of Example 1 instead of the semiconductor laser 200 of Example 2. In this case, the optical module can reduce the threshold current from 10 mA to 5.0 mA at 25° C. The slope efficiency can be increased from 0.2 W/A to 0.33 W/A. Further, the maximum optical output can be increased by 66%.

According to the present invention, it is possible to dramatically improve the laser characteristics and the manufacturing yield of an optical semiconductor element. The laser characteristics and the manufacturing yield are affected by thermal diffusion of dopant in a crystal growth process.

What is claimed is:

1. An optical semiconductor element, comprising:
a lower guide layer formed on an InP substrate,
an active layer,
an upper guide layer,
an etching stop layer of a diffraction grating layer,
a diffraction grating obtained by patterning said diffraction grating layer,
a p-type clad layer, and
a diffusion prevention layer between said diffraction grating and said p-type clad layer,
wherein said diffusion prevention layer preventing dopant of said p-type clad layer from thermally diffusing to said active layer.

2. An optical semiconductor element, comprising:
a lower guide layer formed on an InP substrate,
an active layer,
an upper guide layer,
an etching stop layer of a diffraction grating layer,
a diffraction grating obtained by patterning said diffraction grating layer,
a p-type clad layer, and
a thin film layer between said diffraction grating and said p-type clad layer,
wherein the thin film layer being almost identical in composition to said diffraction grating layer.

3. The optical semiconductor element according to claim 1, wherein said active layer is made of InGaAsP or InGaAlAs.

4. The optical semiconductor element according to claim 2, wherein said active layer is made of InGaAsP or InGaAlAs.

5. The optical semiconductor element according to claim 1, wherein said diffraction grating layer is made of InₓGa₍₁₋ₓ₎As_{y}P_{(1-y)} (0≦x≦1, 0≦y≦1).

6. The optical semiconductor element according to claim 2, wherein said diffraction grating layer is made of InₓGa₍₁₋ₓ₎As_{y}P_{(1-y)} (0≦x≦1, 0≦y≦1).

7. An optical semiconductor element, comprising:
an n-type InAlAs lower guide layer formed on an InP substrate,
an InGaAlAs active layer,
a p-type InAlAs upper guide layer,
an InP etching stop layer of an InGaAsP diffraction grating layer,
a diffraction grating obtained by patterning said diffraction grating layer,
an InGaAsP thin film layer, and
a p-type InP clad layer,
said p-type InP clad layer having a ridge waveguide etched to said InGaAsP thin film layer.

8. An optical module, comprising:
an optical semiconductor element having a lower guide layer formed on an InP substrate, an active layer, an upper guide layer, an etching stop layer of a diffraction grating layer, a diffraction grating obtained by patterning said diffraction grating layer, a p-type clad layer, and a diffusion prevention layer between said diffraction grating and said p-type clad layer,
an optical fiber for transmitting light from said optical semiconductor element, and
a housing for housing said optical semiconductor element and an end of said optical fiber,
wherein said diffusion prevention layer preventing dopant of said p-type clad layer from thermally diffusing to said active layer.

9. A method of manufacturing an optical semiconductor element, comprising:
growing a lower guide layer, an active layer, an upper guide layer, an InP etching stop layer, and a diffraction grating layer on an InP substrate,
working a diffraction grating on said diffraction grating layer of a formation part of a waveguide, and growing a diffusion prevention layer and a p-type InP clad layer on said diffraction grating, said diffusion prevention layer preventing dopant of said p-type InP clad layer from thermally diffusing to said active layer.

10. The method of manufacturing the optical semiconductor element according to claim 9, further comprising etching said p-type InP clad layer on both sides of said waveguide to said diffusion prevention layer.

11. A method of manufacturing an optical semiconductor element, comprising:
growing an InAlAs lower guide layer, an InGaAlAs active layer, an InAlAs upper guide layer, an InP etching stop layer, and a diffraction grating layer on an InP substrate,
working a diffraction grating on said diffraction grating layer of a formation part of a waveguide,
growing a diffusion prevention layer and said p-type InP clad layer on said diffraction grating, said diffusion prevention layer preventing dopant of said p-type InP clad layer from thermally diffusing to said active layer, and
etching said p-type InP clad layer on both sides of said waveguide to said diffusion prevention layer.
